(19) United States
(12) Patent Application Publication
(10) Pub. No.: US 2026/0068290 A1
(43) Pub. Date: Mar. 5, 2026

(54) SEMICONDUCTOR DEVICE AND METHOD FOR MANUFACTURING THE SAME

(71) Applicant: DENSO CORPORATION, Kariya-city (JP)

(72) Inventors: Hiroto SUGIURA, Kariya-city (JP); Atsushi SUGIMURA, Kariya-city (JP); Masanori MIYATA, Kariya-city (JP); Masakiyo SUMITOMO, Kariya-city (JP)

(21) Appl. No.: 19/380,106

(22) Filed: Nov. 5, 2025

Related U.S. Application Data
(63) Continuation of application No. PCT/JP2024/005259, filed on Feb. 15, 2024.

(30) Foreign Application Priority Data
May 11, 2023 (JP) 2023-078489

(51) Int. Cl. H10D 84/00; H10D 12/00; H10D 62/60; H10D 64/27; H10D 84/01

(52) U.S. Cl. CPC H10D 84/161; H10D 12/481; H10D 62/60; H10D 84/0109; H10D 64/513

(57) ABSTRACT

In a semiconductor device, a semiconductor substrate includes: an n-type field stop region distributed across an IGBT region and a diode region; a p-type collector region disposed below the field stop region in the IGBT region; a plurality of n-type cathode regions disposed below the field stop region in the diode region; and a plurality of p-type surge suppression regions disposed below the field stop region in the diode region. In the diode region, the cathode regions and the surge suppression regions are alternately arranged along a specific direction on a lower surface of the semiconductor substrate. Each cathode region includes: a first cathode region in contact with a lower electrode, and having an n-type impurity concentration of 1×10¹⁹ cm⁻³ or more; and a second cathode region between the first cathode region and the field stop region, and having an activation rate of n-type impurity of 85% or less.

### CROSS REFERENCE TO RELATED APPLICATIONS

The present application is a continuation application of International Patent Application No. PCT/JP2024/005259 filed on Feb. 15, 2024, which designated the U.S. and claims the benefit of priority from Japanese Patent Application No. 2023-078489 filed on May 11, 2023. The entire disclosures of all of the above applications are incorporated herein by reference.

### TECHNICAL FIELD

The present disclosure relates to a semiconductor device and a method for manufacturing the semiconductor device.

For example, a method for manufacturing a semiconductor device having an insulated gate bipolar transistor (IGBT) and a diode has been known. Hereinafter, a semiconductor device having an IGBT and a diode may be referred to as a reverse conducting insulated gate bipolar transistor (RC-IGBT). In a known method for manufacturing a semiconductor device, an n-type cathode region is formed by ion implantation of an n-type impurity. Next, crystal defects are formed in the cathode region by irradiating the semiconductor substrate with helium ions. The crystal defects formed in the cathode region suppress snapback, which occurs when the IGBT is turned on.

### SUMMARY

According to an aspect of the present disclosure, a semiconductor device includes: a semiconductor substrate having an insulated gate bipolar transistor (IGBT) region and a diode region; an upper electrode in contact with an upper surface of the semiconductor substrate in the IGBT region and the diode region; a lower electrode in contact with a lower surface of the semiconductor substrate in the IGBT region and the diode region; and a gate electrode. The semiconductor substrate may include: an emitter region of an n-type in contact with the upper electrode in the IGBT region; an upper p-type region distributed across the IGBT region and the diode region and in contact with the upper electrode in the IGBT region and the diode region; a drift region of the n-type disposed below the upper p-type region, distributed across the IGBT region and the diode region, and separated from the n-type emitter region by the upper p-type region; a field stop region of the n-type disposed below the drift region, distributed across the IGBT region and the diode region, and having an n-type impurity concentration which is higher than that of the drift region and has a mountain-shaped distribution along a thickness direction of the semiconductor substrate; a collector region of a p-type disposed below the field stop region in the IGBT region, and in contact with the lower electrode; a plurality of cathode regions of the n-type disposed below the field stop region in the diode region, and in contact with the lower electrode; and a plurality of surge suppression regions of the p-type disposed below the field stop region in the diode region, and in contact with the lower electrode. The gate electrode may face the upper p-type region between the emitter region and the drift region via a gate insulating film. In the diode region, the plurality of cathode regions and the plurality of surge suppression regions may be alternately arranged along a specific direction on the lower surface of the semiconductor substrate. Each of the plurality of cathode regions includes: a first cathode region in contact with the lower electrode, and having an n-type impurity concentration of 1×10¹⁹ cm⁻³ or more; and a second cathode region disposed between the first cathode region and the field stop region, and having an activation rate of n-type impurity of 85% or less.

### BRIEF DESCRIPTION OF DRAWINGS

Features and advantages of the present disclosure will become more apparent from the following detailed description made with reference to the accompanying drawings, in which:

FIG. 1 is a cross-sectional view of a semiconductor device according to a first embodiment;

FIG. 2 is a graph showing an impurity concentration distribution at the position along a line A-A in FIG. 1;

FIG. 3 is a graph showing an impurity concentration distribution at the positions along lines B-B and C-C in FIG. 1;

FIG. 4 is a graph showing recovery characteristics when a switching speed of voltage Vak is slow;

FIG. 5 is a graph showing recovery characteristics when the switching speed of voltage Vak is fast;

FIG. 6 is a cross-sectional view for explaining a manufacturing process of the semiconductor device according to the first embodiment;

FIG. 7 is a cross-sectional view for explaining a manufacturing process of the semiconductor device according to the first embodiment;

FIG. 8 is a cross-sectional view for explaining a manufacturing process of the semiconductor device according to the first embodiment;

FIG. 9 is a cross-sectional view for explaining a manufacturing process of the semiconductor device according to the first embodiment;

FIG. 10 is a graph showing an impurity concentration distribution at the position along the line A-A in a semiconductor device according to a second embodiment; and

FIG. 11 is a graph showing an impurity concentration distribution at the positions along the lines B-B and C-C in a semiconductor device according to a third embodiment.

### DETAILED DESCRIPTION

In an RC-IGBT, when the voltage applied to a diode is switched from a forward voltage to a reverse voltage, holes present inside the diode are discharged to an anode electrode. As a result, a recovery current is caused to flow in the diode in a reverse direction. In an RC-IGBT in which crystal defects are formed in a cathode region, the crystal defects function as recombination centers. Therefore, during a recovery operation, holes are recombined at the crystal defects and disappear, causing the recovery current to decay quickly. This reduces the recovery loss of the diode.

The voltage applied to the diode may change rapidly. When the voltage applied to the diode is switched from the forward voltage to the reverse voltage at high speed, the recovery current may decay too quickly, resulting in a surge voltage. In the case where the crystal defects exits in the cathode region, the recovery current decays easily, and the surge voltage is likely to occur.

As described above, in the case where the crystal defects exist in the cathode region, the recovery loss can be reduced. However, the surge voltage is likely to occur when the applied voltage changes at high speed. The present disclosure provides a technique for suppressing surge voltage while reducing recovery loss in an RC-IGBT.

In an embodiment of the present disclosure, a semiconductor device includes: a semiconductor substrate having an IGBT region and a diode region; an upper electrode in contact with an upper surface of the semiconductor substrate in the IGBT region and the diode region; a lower electrode in contact with a lower surface of the semiconductor substrate in the IGBT region and the diode region; and a gate electrode. The semiconductor substrate includes an emitter region, an upper p-type region, a drift region, a field stop region, a collector region, a plurality of cathode regions, and a plurality of surge suppression regions. The emitter region is an n-type region in contact with the upper electrode in the IGBT region. The upper p-type region is distributed across the IGBT region and the diode region, and is in contact with the upper electrode in the IGBT region and the diode region. The drift region is an n-type region, and is distributed across the IGBT region and the diode region. The drift region is located below the upper p-type region, and separated from the emitter region by the upper p-type region. The field stop region is an n-type region, and is distributed across the IGBT region and the diode region. The field stop region is located below the drift region. The field stop region has an n-type impurity concentration higher than that of the drift region. Further, the n-type impurity concentration of the field stop region has a mountain-shaped distribution along a thickness direction of the semiconductor substrate. The collector region is a p-type region located below the field stop region in the IGBT region, and is in contact with the lower electrode. The plurality of cathode regions are n-type regions located below the field stop region in the diode region, and are in contact with the lower electrode. The plurality of surge suppression regions are p-type regions located below the field stop region in the diode region, and are in contact with the lower electrode. The gate electrode faces the upper p-type region between the emitter region and the drift region via a gate insulating film. In the diode region, the plurality of cathode regions and the plurality of surge suppression regions are alternately arranged along a specific direction on the lower surface of the semiconductor substrate. Each of the plurality of cathode regions has a first cathode region that is in contact with the lower electrode and has an n-type impurity concentration of 1×10¹⁹ cm⁻³ or more, and a second cathode region that is disposed between the first cathode region and the field stop region and has an n-type impurity activation rate of 85% or less.

In this specification, the upper p-type region may be any p-type region as long as it is distributed across the IGBT region and the diode region and is in contact with the upper electrode in the IGBT region and the diode region. For example, the upper p-type region in the IGBT region and the upper p-type region in the diode region may have the same profile in the p-type impurity concentration, or may have different profiles in the p-type impurity concentration.

In such a semiconductor device, the upper electrode functions as an emitter electrode of the IGBT as well as an anode electrode of the diode. Further, the lower electrode functions as a collector electrode of the IGBT as well as a cathode electrode of the diode. The cathode region includes the first cathode region and the second cathode region. Since the first cathode region has the n-type impurity concentration of 1×10¹⁹ cm⁻³ or more, the first cathode region is in contact with the lower electrode with low contact resistance. Therefore, it is less likely that loss will occur when the diode is turned on. Furthermore, since the activation rate of the n-type impurity in the second cathode region is 85% or less, a large amount of inactivated n-type impurity exists in the second cathode region. The inactivated n-type impurity in the second cathode region forms crystal defects, which function as recombination centers for holes. In the diode region, the p-type surge suppression region is disposed adjacent to the cathode region. When the voltage applied to the diode is switched from a forward voltage to a reverse voltage at high speed, a recovery current flows in the diode. The crystal defects, that is, the inactivated n-type impurity in the second cathode region acts to decay the recovery current. On the other hand, when the voltage applied to the diode is switched from the forward voltage to the reverse voltage at high speed, holes are injected from the surge suppression regions into the drift region. When the holes are injected into the drift region in this way, the recovery current does not decay easily. Therefore, when the voltage applied to the diode is changed from the forward voltage to the reverse voltage at high speed, the rapid decay of the recovery current is suppressed, and the occurrence of the surge voltage is suppressed. Furthermore, when the voltage applied to the diode is switched from the forward voltage to the reverse voltage at a normal speed, almost no holes are injected from the surge suppression regions into the drift region. In this case, therefore, the crystal defects in the second cathode region cause the recovery current to decay rapidly. As such, the recovery loss can be reduced. In this way, the semiconductor device described above can suppress the recovery loss during a normal recovery operation, and can suppress the surge voltage when the applied voltage is switched rapidly.

In an embodiment of the present disclosure, the second cathode region may have a mountain-shaped distribution in an n-type impurity concentration along a thickness direction of the semiconductor substrate.

By increasing the n-type impurity concentration in the second cathode region in this manner, the activation rate in the second cathode region can be further reduced. Therefore, the recovery loss can be more effectively suppressed.

In an embodiment of the present disclosure, the mountain-shaped distribution in the n-type impurity concentration of the second cathode region may have a peak value higher than 1×10¹⁸ cm⁻³ and lower than 1×10¹⁹ cm⁻³.

The semiconductor devices in embodiments described above may be manufactured by the following manufacturing method. The manufacturing method may include an ion-implantation process and a laser beam application process. In the ion-implantation process, the collector region, the cathode regions, and the surge suppression regions may be formed by ion implantation of a p-type impurity and an n-type impurity into the lower surface of the semiconductor substrate. In the laser beam application process, a laser beam may be applied to the lower surface of the semiconductor substrate after the collector region, the cathode regions, and the surge suppression regions are formed. In the laser beam application process, a heated area of 950 degrees Celsius (° C.) or higher may be formed in a surface layer portion of the semiconductor substrate near the lower surface. The thickness of the heated area may be less than the thickness of the cathode region.

According to the manufacturing method, the activation rate of the n-type impurity in the second cathode region can be reduced.

### First Embodiment

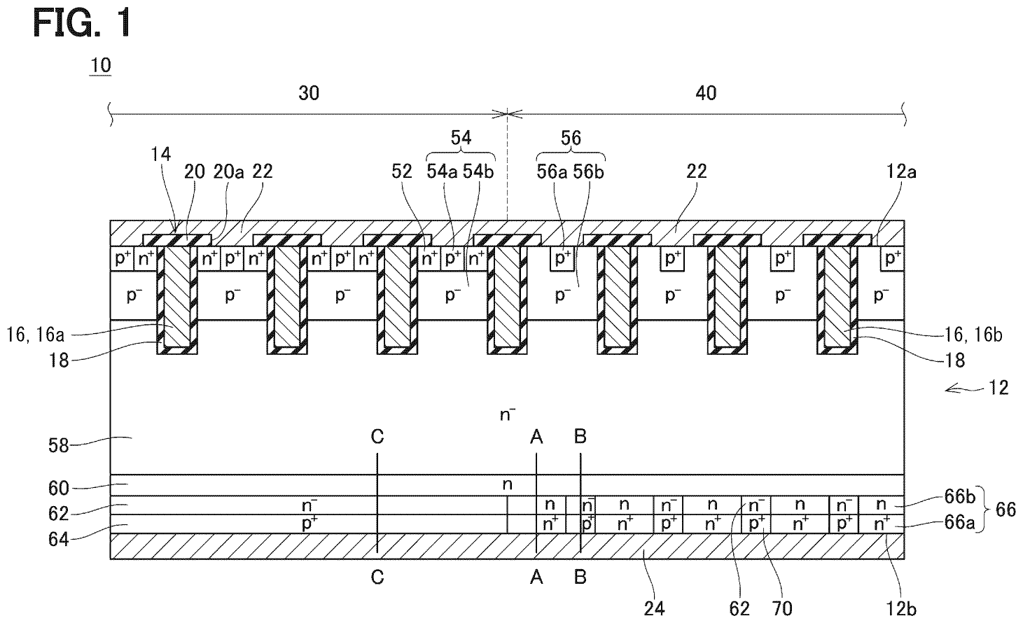

As illustrated in FIG. 1, a semiconductor device 10 according to a first embodiment includes a semiconductor substrate 12. The semiconductor substrate 12 is made of silicon. However, the semiconductor substrate 12 may be made of a semiconductor material other than silicon. The semiconductor substrate 12 has an IGBT region 30 and a diode region 40. The IGBT region 30 is provided with an IGBT and the diode region 40 is provided with a diode. That is, the semiconductor device 10 is an RC-IGBT.

The semiconductor substrate 12 is formed with a plurality of trenches 14 on an upper surface 12a. The trenches 14 extend parallel to one another on the upper surface 12a. Each of the IGBT region 30 and the diode region 40 is formed with the plurality of trenches 14. An inner surface of each of the trenches 14 is covered with a gate insulating film 18. An electrode 16 is disposed in each of the trenches 14. Each of the electrodes 16 is insulated from the semiconductor substrate 12 by the gate insulating film 18. The electrode 16 in the IGBT region 30 serves as a gate electrode 16a. Each gate electrode 16a is connected to a gate pad (not shown). An external circuit is connected to the gate pad. The potential of each gate electrode 16a is controlled by an external circuit. Each gate electrode 16 in the diode region 40 is a dummy electrode 16b. Each dummy electrode 16b may be connected to a gate pad, or may be connected to another electrode (for example, the upper electrode 22) without being connected to the gate pad. In a case where each dummy electrode 16b is connected to the gate pad, the dummy electrode 16b has the same potential as the gate electrode 16a. In a case where each dummy electrode 16b is not connected to a gate pad, the potential of each dummy electrode 16b is independent of the gate electrode 16a.

An interlayer insulating film 20 and an upper electrode 22 are provided on the semiconductor substrate 12. The interlayer insulating film 20 covers the upper surfaces of the gate electrodes 16a and the dummy electrodes 16b. The interlayer insulating film 20 is formed with a plurality of contact holes 20a. Each contact hole 20a is disposed at a position where no trench 14 is present. A plurality of contact holes 20a are disposed in each of the IGBT region 30 and the diode region 40. The upper electrode 22 covers the interlayer insulating film 20 and the upper surface 12a of the semiconductor substrate 12. The upper electrode 22 is in contact with the upper surface 12a of the semiconductor substrate 12 in each of the contact holes 20a. Therefore, the upper electrode 22 is in contact with the upper surface 12a in both the IGBT region 30 and the diode region 40.

A lower electrode 24 is provided at a lower part of the semiconductor substrate 12. The lower electrode 24 covers the entire lower surface 12b of the semiconductor substrate 12. Therefore, the lower electrode 24 is in contact with the lower surface 12b in both the IGBT region 30 and the diode region 40.

A plurality of n-type emitter regions 52 are provided in the IGBT region 30. Each emitter region 52 has a high n-type impurity concentration. Each emitter region 52 is disposed in a region between the trenches 14 (hereinafter referred to as an inter-trench region). Each emitter region 52 is disposed in a range including the upper surface 12a of the semiconductor substrate 12. Each emitter region 52 is in ohmic contact with the upper electrode 22 through a corresponding contact hole 20a. Each emitter region 52 is in contact with the gate insulating film 18 at an upper end of a side surface of the corresponding trench 14.

An upper p-type region is provided across the IGBT region 30 and the diode region 40. Hereinafter, the upper p-type region in the IGBT region 30 will be referred to as a body region 54, and the upper p-type region in the diode region 40 will be referred to as an anode region 56. The upper p-type region is in contact with the upper electrode 22 at each of the contact holes 20a in the IGBT region 30 and the diode region 40.

The body region 54 has a low concentration region 54b and a plurality of contact regions 54a. Each contact region 54a has a p-type impurity concentration higher than that of the low concentration region 54b. Each contact region 54a is disposed in a corresponding inter-trench region. Each contact region 54a is disposed in a range including the upper surface 12a of the semiconductor substrate 12. Each contact region 54a is in ohmic contact with the upper electrode 22 in the corresponding contact hole 20a. The low concentration region 54b is distributed across the plurality of inter-trench regions. The low concentration region 54b is disposed below the contact region 54a and the emitter region 52. Each emitter region 52 is separated from the drift region 58, which will be described later, by the low concentration region 54b. The low concentration region 54b is in contact with the gate insulating film 18 below each emitter region 52. Each gate electrode 16a faces the low concentration region 54b between the emitter region 52 and the drift region 58 via the gate insulating film 18.

The anode region 56 has a low concentration region 56b and a plurality of contact regions 56a. Each contact region 56a has a p-type impurity concentration higher than that of the low concentration region 56b. Each contact region 56a is disposed in a corresponding inter-trench region. Each contact region 56a is disposed in a range including the upper surface 12a of the semiconductor substrate 12. Each contact region 56a is in ohmic contact with the upper electrode 22 in the corresponding contact hole 20a. The low concentration region 56b is distributed across the plurality of inter-trench regions. The low concentration region 56b is disposed below the contact region 56a.

An n-type drift region 58 is provided below the upper p-type region (i.e., the body region 54 and the anode region 56). An n-type impurity concentration of the drift region 58 is low. The drift region 58 is distributed across the IGBT region 30 and the diode region 40. The drift region 58 is in contact with the body region 54 and the anode region 56 from below. The drift region 58 is in contact with the gate insulating films 18 below the body region 54 and the anode region 56.

A field stop region 60 is provided below the drift region 58. The field stop region 60 is an n-type region having an n-type impurity concentration higher than that of the drift region 58. The field stop region 60 is distributed across the IGBT region 30 and the diode region 40. The field stop region 60 is in contact with the drift region 58 from below.

In the IGBT region 30, an intermediate n-type region 62 and a collector region 64 are disposed below the field stop region 60. The collector region 64 is a p-type region having a high p-type impurity concentration. The collector region 64 is disposed in a range including the lower surface 12b of the semiconductor substrate 12 and is in ohmic contact with the lower electrode 24. The intermediate n-type region 62 is an n-type region having an n-type impurity concentration similar to the n-type impurity concentration of the drift region 58. In the IGBT region 30, the intermediate n-type region 62 is disposed between the field stop region 60 and the collector region 64.

In the diode region 40, a plurality of intermediate n-type regions 62, a plurality of cathode regions 66 and a plurality of surge suppression regions 70 are disposed below the field stop region 60. Each cathode region 66 is an n-type region having an n-type impurity concentration higher than that of the drift region 58. Each cathode region 66 is disposed in a range that includes the lower surface 12b of the semiconductor substrate 12. Each surge suppression region 70 is a p-type region having a high p-type impurity concentration. The p-type impurity concentration of each surge suppression region 70 is approximately equal to the p-type impurity concentration of the collector region 64. Each surge suppression region 70 is disposed in a range that includes the lower surface 12b of the semiconductor substrate 12. In the diode region 40, the plurality of cathode regions 66 and the plurality of surge suppression regions 70 are alternately arranged on the lower surface 12b of the semiconductor substrate 12 along a specific direction (e.g., a direction perpendicular to each trench 14 in FIG. 1). Each cathode region 66 and each surge suppression region 70 are in ohmic contact with the lower electrode 24. In the diode region 40, the intermediate n-type region 62 is disposed between the field stop region 60 and the surge suppression region 70.

Each cathode region 66 has a first cathode region 66a having an n-type impurity concentration of 1×10¹⁹ cm⁻³ or more, and a second cathode region 66b having an n-type impurity concentration of less than 1×10¹⁹ cm⁻³. The first cathode region 66a is disposed in a range including the lower surface 12b of the semiconductor substrate 12. The first cathode region 66a is in ohmic contact with the lower electrode 24. The second cathode region 66b is disposed between the first cathode region 66a and the field stop region 60. The second cathode region 66b is in contact with the field stop region 60 from below. The second cathode region 66b is in contact with the first cathode region 66a from above.

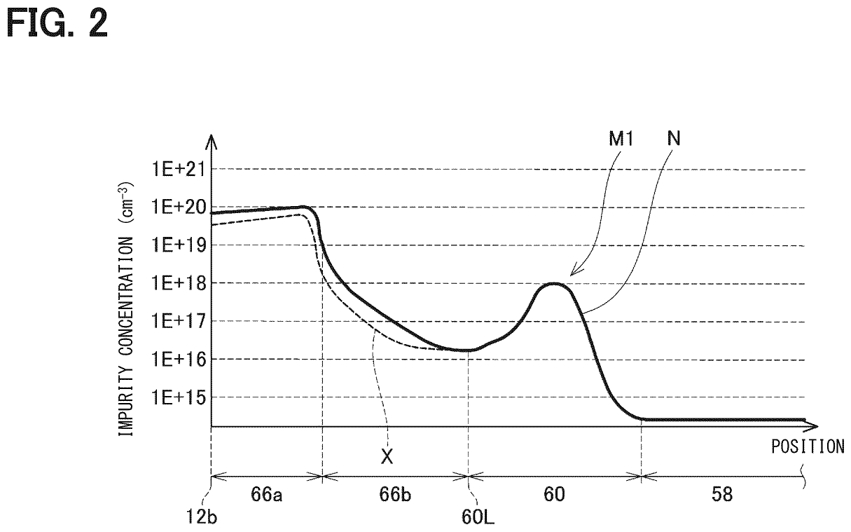

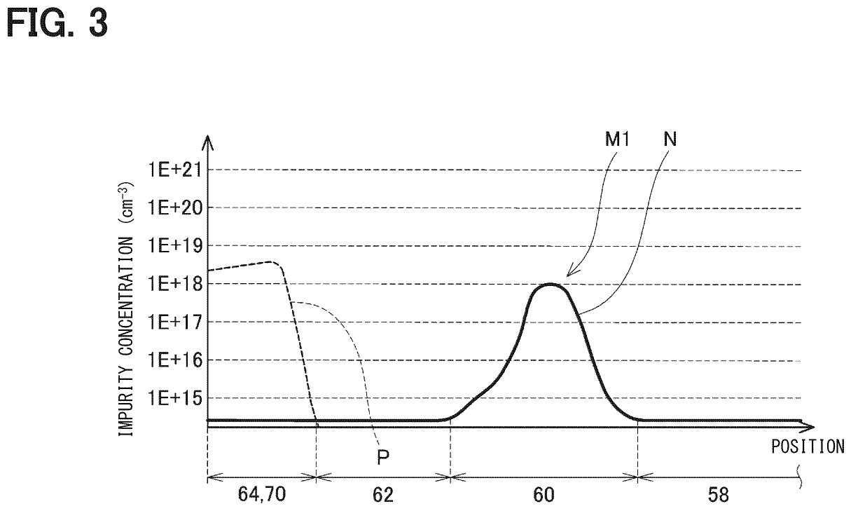

Next, the impurity concentration distributions in the drift region 58, the field stop region 60, the intermediate n-type region 62, the collector region 64, the cathode region 66, and the surge suppression region 70 will be described. FIG. 2 shows the impurity concentration distributions at a position along a line A-A in FIG. 1, and FIG. 3 shows the impurity concentration distribution at positions along the line B-B and the line C-C in FIG. 1. The impurity concentration distribution along the line B-B and the impurity concentration distribution along the line C-C are approximately the same. In FIGS. 2 and 3, the horizontal axis represents the position in the thickness direction of the semiconductor substrate 12, with the origin corresponding to the position of the lower surface 12b. In FIGS. 2 and 3, a graph N indicates an n-type impurity concentration distribution, and a graph P indicates a p-type impurity concentration distribution.

As shown in FIGS. 2 and 3, in the drift region 58, the n-type impurity concentration is distributed substantially uniformly at a low value.

As shown in FIGS. 2 and 3, in the field stop region 60, the n-type impurity concentration forms a mountain-shaped distribution M1 in the thickness direction of the semiconductor substrate 12. That is, the field stop region 60 is a region where the mountain-shaped distribution M1 in the thickness direction exists continuously from the IGBT region 30 to the diode region 40. The peak value of the n-type impurity concentration in the field stop region 60 is less than 1×10¹⁹ cm⁻³.

As shown in FIG. 2, the n-type impurity concentration in the first cathode region 66a is 1×10¹⁹ cm⁻³ or more. In the first cathode region 66a, the n-type impurity concentration is distributed at a substantially constant high value (for example, about 1×10²⁰ cm⁻³ in FIG. 2). In other words, in the first cathode region 66a, the n-type impurity is distributed in a box profile. The second cathode region 66b is the n-type region between the field stop region 60 and the first cathode region 66a. The n-type impurity concentration in the second cathode region 66b is higher than the n-type impurity concentration at a lower end 60L of the field stop region 60 and is less than 1×10¹⁹ cm⁻³. In FIG. 2, the n-type impurity concentration increases continuously from the top position to the bottom position in the second cathode region 66b.

As shown in FIG. 3, in the intermediate n-type region 62, the collector region 64 and the surge suppression region 70, the n-type impurity concentration is uniformly distributed at a value similar to that in the drift region 58. In the collector region 64 and the surge suppression region 70, the p-type impurity concentration is higher than the n-type impurity concentration. In the collector region 64 and the surge suppression region 70, the p-type impurity is distributed in a box profile.

The graph X in FIG. 2 shows the concentration distribution of an activated n-type impurity. That is, the graph N shows the concentration distribution of n-type impurity, which is a combination of the activated n-type impurity and the non-activated n-type impurity, while the graph X shows the concentration distribution of the activated n-type impurity. The values shown by the graph X (i.e., the concentration of the activated n-type impurity) are the values calculated from the measurement results obtained by measuring the distribution of resistance in the semiconductor substrate 12 along the thickness direction. The difference between the graph N and the graph X corresponds to the concentration of the non-activated n-type impurity. As shown in FIG. 2, the difference between the graph N and the graph X is large in the second cathode region 66b. The activation rate of the n-type impurity in the second cathode region 66b is 85% or less. In this specification, the activation rate means the value obtained by dividing the total amount of activated n-type impurity in the target region by the total amount of n-type impurity present in the target region. For example, the activation rate in the second cathode region 66b can be calculated by dividing the value, which is obtained by integrating the graph X in the second cathode region 66b, by the value, which is obtained by integrating the graph N in the second cathode region 66b. Since the activation rate of the n-type impurity is low in the second cathode region 66b, the non-activated n-type impurity is present with a high concentration in the second cathode region 66b. The non-activated impurity in the semiconductor substrate 12 is a type of crystal defect and acts as a carrier recombination center. Therefore, the carrier lifetime is short in the second cathode region 66b. As shown in FIG. 2, the activation rate of n-type impurity is higher in the first cathode region 66a than in the second cathode region 66b. For example, the activation rate of the n-type impurity in the first cathode region 66a may be higher than 85%.

Next, the operation of the semiconductor device 10 will be described. The upper electrode 22 functions as the emitter electrode of the IGBT and also the anode electrode of the diode. The lower electrode 24 functions as the collector electrode of the IGBT and also as the cathode electrode of the diode.

When the semiconductor device 10 operates as the IGBT, a higher potential is applied to the lower electrode 24 than to the upper electrode 22. When a potential equal to or higher than the gate threshold is applied to the gate electrode 16a, a channel is formed in the low concentration region 54b adjacent to the gate insulating film 18, and the emitter region 52 and the drift region 58 are connected by the channel. As a result, the IGBT is turned on, so that electrons flow from the emitter region 52 into the drift region 58 via the channel. When the IGBT is turned on, holes flow from the collector region 64 into the drift region 58. This reduces the resistance of the drift region 58, allowing electrons to flow through the drift region 58 with low resistance. After passing through drift region 58, the electrons flow to the collector region 64.

In the RC-IGBT, the electrons flow from the drift region 58 to the cathode region 66 when the IGBT begins to turn on (that is, when the channel resistance is high). In this state, the on-voltage of the IGBT is high. Thereafter, when the resistance of the channel decreases, the electrons begin to flow from the drift region 58 to the collector region 64, and the on-voltage of the IGBT decreases. This phenomenon in which the on-voltage temporarily increases at the beginning of turn-on is referred to as snapback. In the semiconductor device 10 of the first embodiment, the cathode regions 66 and the surge suppression regions 70 are alternately arranged in the diode region 40, so the area ratio of the cathode regions 66 on the lower surface 12b is small. Therefore, when the IGBT is turned on, the electrons are less likely to flow from the drift region 58 to the cathode regions 66. For this reason, the snapback is suppressed.

When the semiconductor device 10 operates as a diode, a higher potential is applied to the upper electrode 22 than to the lower electrode 24. In this state, the electrons flow from the cathode regions 66 into the drift region 58. Further, the holes flow from the anode region 56 into the drift region 58. This reduces the resistance of the drift region 58, allowing the electrons to flow through the drift region 58 with low resistance. The electrons flow to the anode region 56, after passing through the drift region 58. The holes flow to the cathode regions 66, after passing through the drift region 58.

In a state where the semiconductor device 10 is operating as the diode, the voltage Vak between the upper electrode 22 and the lower electrode 24 may switch from a forward voltage (i.e., a voltage at which the potential of the upper electrode 22 is higher than the potential of the lower electrode 24) to a reverse voltage (i.e., a voltage at which the potential of the lower electrode 24 is higher than the potential of the upper electrode 22). When the voltage Vak is switched in this way, the diode performs a recovery operation. In the recovery operation of the diode, the holes existing in the drift region 58, the field stop region 60 and the cathode regions 66 are discharged to the upper electrode 22 via the anode region 56. The flow of holes in this way causes a reverse current to instantaneously flow through the diode. This reverse current is so-called a recovery current. By rapidly decreasing the recovery current, the recovery loss can be suppressed. On the other hand, if the recovery current is decayed too rapidly, a surge voltage occurs due to the rapid change in the recovery current. In the semiconductor device of the first embodiment, the operation of the diode changes depending on whether the switching speed of the voltage Vak is fast or slow, and this achieves both the reduction in recovery loss and the suppression of surge. The operation of the semiconductor device of the first embodiment will be described below for respective cases where the switching speed of the voltage Vak is slow and fast.

<Case where Switching Speed of Voltage Vak is Slow>

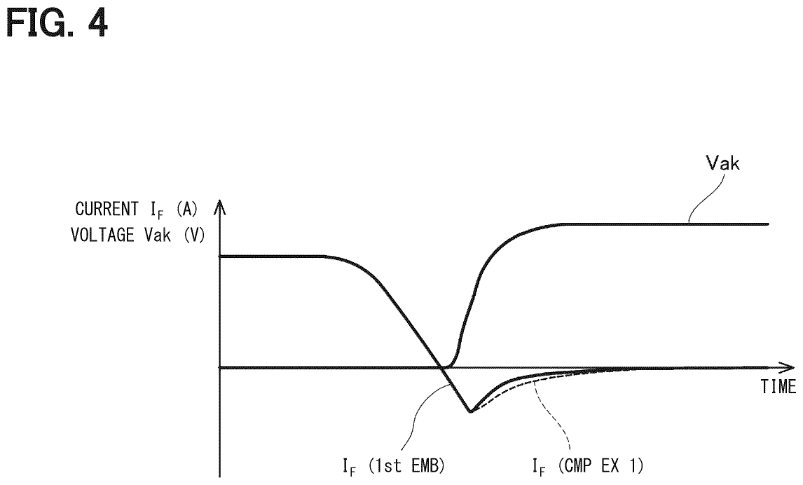

FIG. 4 shows a comparison of the recovery characteristics of the diode of the first embodiment and the diode of a comparative example 1 in the case where the switching speed of the voltage Vak is slow. The diode of the comparative example 1 is different from the diode of the first embodiment in that the activation rate of n-type impurity in the second cathode region 66b is higher than that in the first embodiment. In FIG. 4, the voltage Vak is shown with the cathode (i.e., the lower electrode 24) having a higher potential as positive. In FIG. 4, the graph of the voltage Vak of the first embodiment and the graph of the voltage Vak of the comparative example 1 overlap. In FIG. 4, a current IF represents the current flowing through the diode. A positive value indicates a current flowing in a forward direction, and a negative value indicates a current flowing in a reverse direction.

In FIG. 4, the recovery state occurs when the current IF has the negative value. In the recovery state, holes existing in the drift region 58, the field stop region 60 and the cathode regions 66 are discharged to the upper electrode 22 via the anode region 56. The holes closer to the anode region 56 are more easily discharged to the upper electrode 22. Therefore, it takes time for the holes existing in the cathode regions 66 to be discharged to the upper electrode 22. In the diode of the comparative example 1, the recovery current flows until the holes existing in the cathode regions 66 are discharged to the upper electrode 22, and therefore the recovery current does not decay easily. In contrast to this, in the diode of the present embodiment, the activation rate of the n-type impurity in the second cathode region 66b is low, and therefore the carrier lifetime in the second cathode region 66b is short. Therefore, a large number of holes disappear in the second cathode region 66b by recombination with electrons. For this reason, in the diode of the first embodiment, the recovery current decays faster than in the diode of the comparative example 1. Therefore, in the diode of the present embodiment, recovery loss is less likely to occur. The surge suppression region 70 has almost no effect on the characteristics of the diode when the switching speed of the voltage Vak is slow.

<Case where Switching Speed of Voltage Vak is Fast>

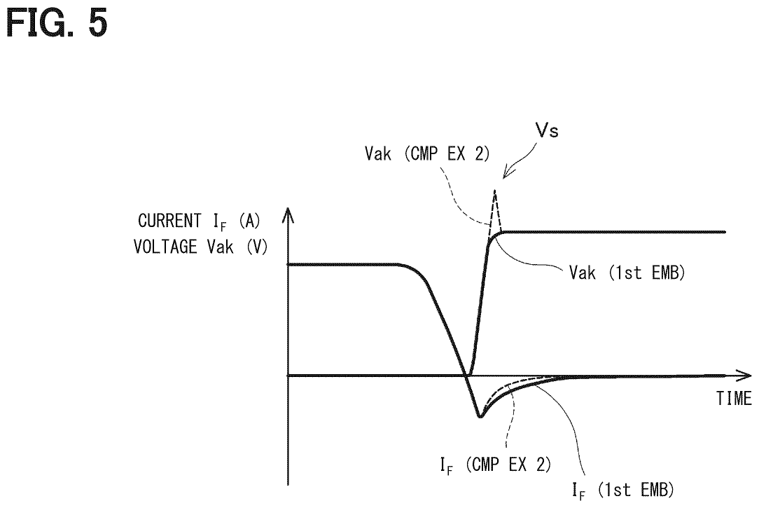

FIG. 5 shows a comparison of the recovery characteristics of the diode of the first embodiment and the diode of a comparative example 2 in the case where the switching speed of the voltage Vak is fast. In the diode of the comparative example 2, similar to the diode of the first embodiment, the activation rate of the n-type impurity in the second cathode region 66b is low. The diode of the comparative example 2 is different from the diode of the first embodiment in that it does not have the surge suppression regions 70.

In the diode of the comparative example 2, since the activation rate of the n-type impurity in the second cathode region 66b is low, the recovery current decays easily. Therefore, when the switching speed of the voltage Vak is fast, the decay rate of the recovery current becomes extremely fast as shown in FIG. 5. As a result, a surge voltage Vs occurs during the recovery operation due to the influence of parasitic inductance in the electric circuit. On the other hand, in the diode of the first embodiment, when the switching speed of the voltage Vak is fast, holes flow from the surge suppression regions 70 into the drift region 58. The flow of holes into the drift region 58 slows down the decay rate of the recovery current. This restricts the recovery current from decaying too quickly, as shown in FIG. 5, and suppresses the surge voltage.

As described above, in the semiconductor device of the first embodiment, when the switching speed of the voltage Vak is slow, the second cathode region 66b promotes the decay of the recovery current, thereby reducing the recovery loss. Furthermore, in the semiconductor device of the first embodiment, when the switching speed of the voltage Vak is fast, the surge suppression regions 70 restrict the decay rate of the recovery current from becoming excessively fast, thereby suppressing the surge voltage.

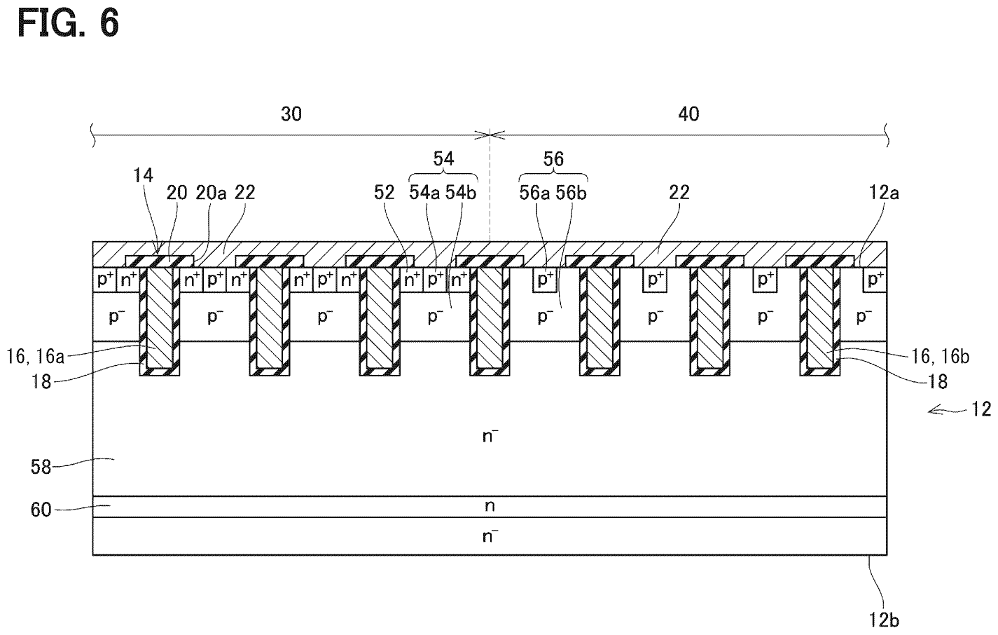

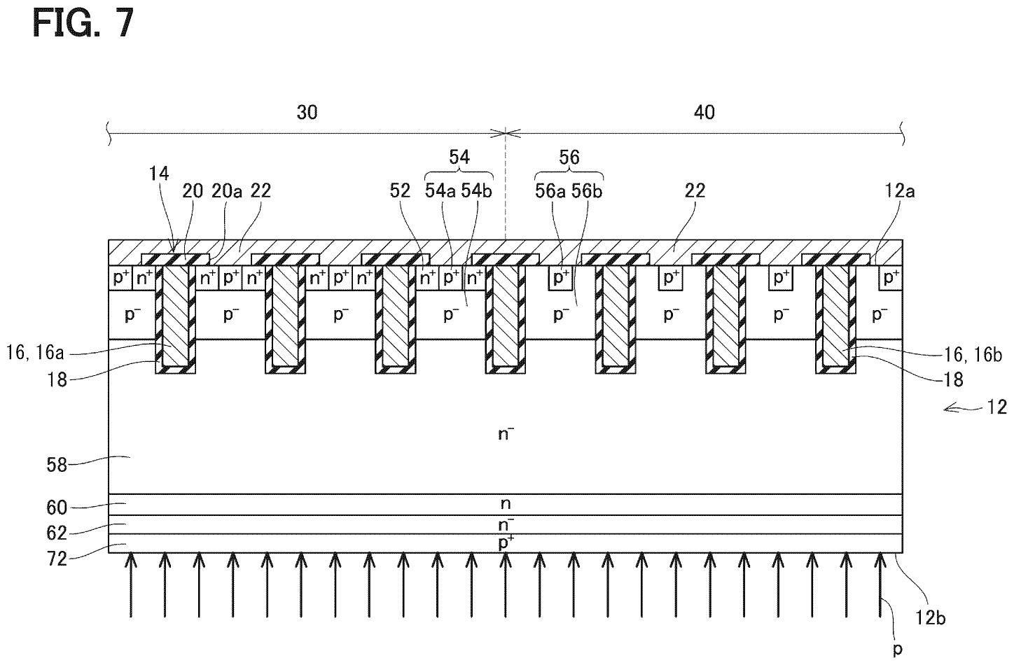

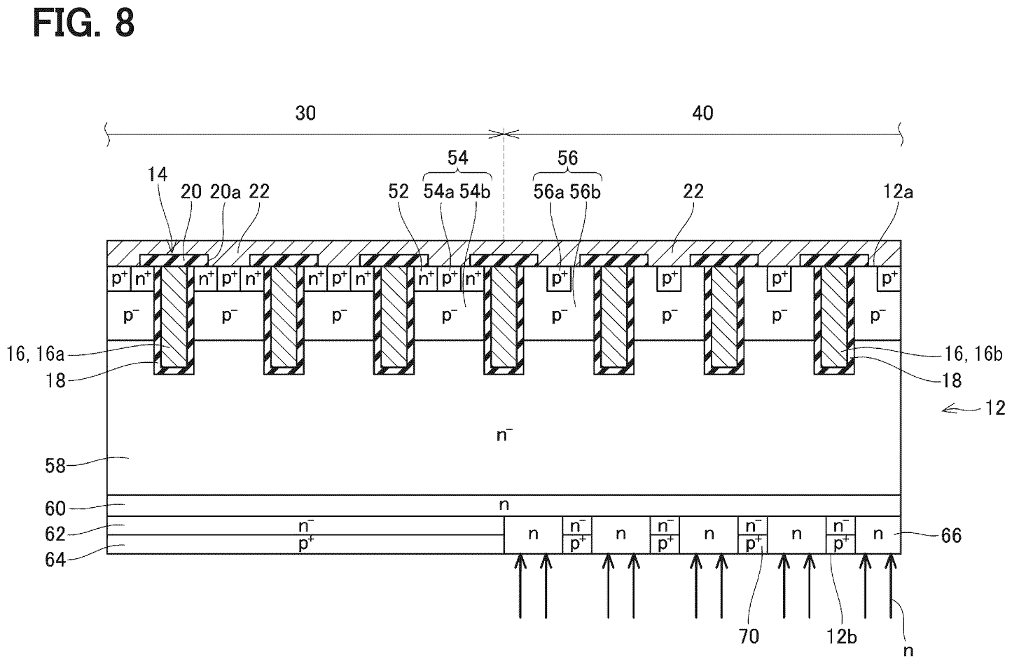

Next, a manufacturing method of the semiconductor device 10 will be described. First, as shown in FIG. 6, the structure on the upper surface side of the semiconductor device 10 and the field stop region 60 are formed. Next, as shown in FIG. 7, a p-type impurity is implanted into the entire lower surface 12b of the semiconductor substrate 12, thereby forming the p-type region 72 in the surface layer near the lower surface 12b. The p-type region 72 is a p-type region that corresponds to the collector region 64 and the surge suppression region 70. Next, as shown in FIG. 8, an n-type impurity is implanted into a portion of the lower surface 12b (i.e., an area corresponding to the cathode region 66) at a concentration higher than the p-type impurity concentration of the p-type region 72, thereby forming the cathode regions 66. In this case, the cathode regions 66 are made thicker than the p-type region 72. The p-type region 72 remaining after the formation of the cathode regions 66 becomes the collector region 64 and the surge suppression regions 70.

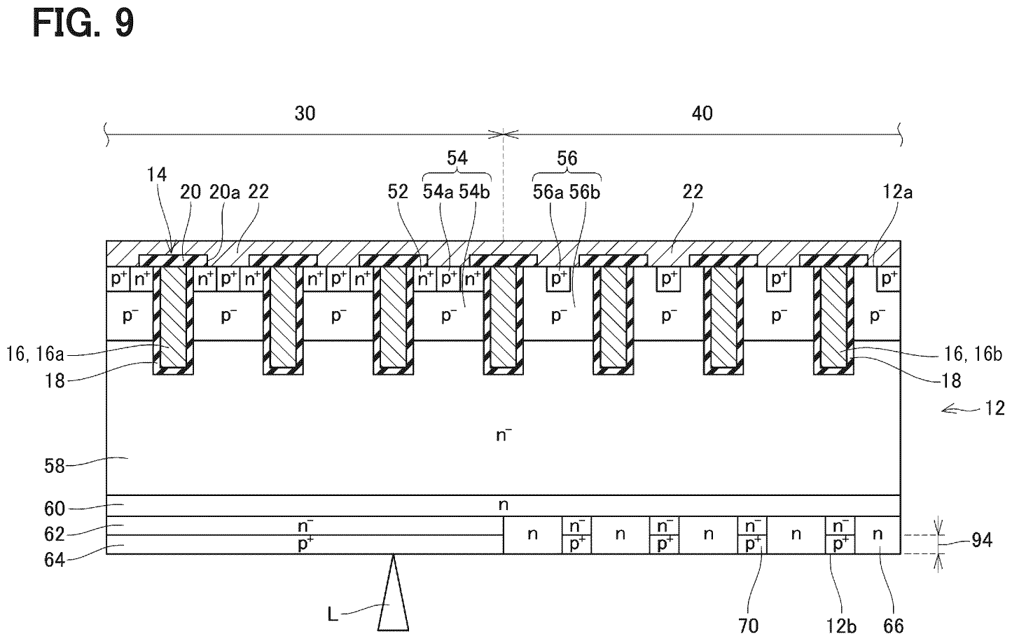

Next, as shown in FIG. 9, a laser beam L is applied to the lower surface 12b of the semiconductor substrate 12 so as to scan the entire lower surface 12b, thereby heating the lower surface 12b. In the present embodiment, a green laser beam with a wavelength of 532 nm is used as the laser beam L. By irradiating the lower surface 12b with the laser beam L, the surface layer portion of the semiconductor substrate 12 near the lower surface 12b is heated to the temperature of 950° C. or higher. Hereinafter, the range heated to the temperature of 950° C. or higher by irradiation with the laser beam L will be referred to as a heated area 94. Within the heated area 94, the semiconductor substrate 12 is temporarily melted. When the semiconductor substrate 12 is temporarily melted, impurities are uniformly diffused within the heated area 94. As a result, the first cathode region 66a, the surge suppression regions 70, and the collector region 64, which have the box profiles, are formed within the heated area 94, as shown in FIGS. 1 through 3. In this case, the heated area 94 is controlled so that the thickness of the heated area 94 is thinner than the thickness of the cathode region 66. Therefore, the portion of the cathode region 66 above the heated area 94 becomes the second cathode region 66b, which has the n-type impurity concentration lower than that of the first cathode region 66a. Since the second cathode region 66b is not included in the heated area 94, the n-type impurity in the second cathode region 66b is not easily activated. Therefore, the second cathode region 66b having the low activation rate is formed.

After the laser application, the lower electrode 24 is formed. Thus, the semiconductor device shown in FIG. 1 is completed. Since the first cathode regions 66a, the surge suppression regions 70, and the collector region 64 have the high impurity concentrations, these regions are in contact with the lower electrode 24 with a low contact resistance.

In FIG. 2, the activation rate of the n-type impurity in the first cathode region 66a is not so high, but this is because the n-type impurity concentration in the first cathode region 66a is close to the solid solubility limit. In contrast to this, in the second cathode region 66b, although the n-type impurity concentration is not so high, the activation rate of the n-type impurity is low. This is because the second cathode region 66b is not included in the heated area 94 in the process of applying the laser beam.

### Second Embodiment

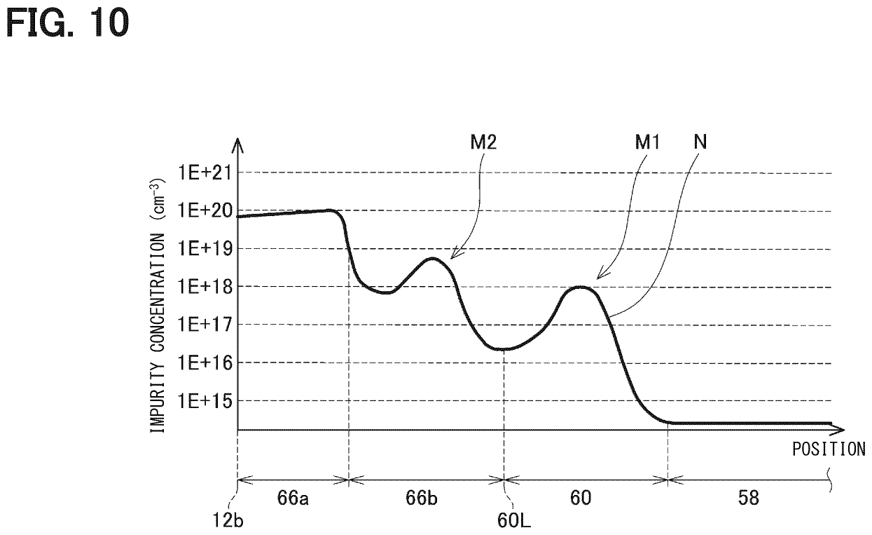

FIG. 10 shows an impurity concentration distribution at the position along the line A-A in a semiconductor device according to a second embodiment. In the second embodiment, the n-type impurity concentration of the second cathode region 66b has a mountain-shaped distribution M2. The peak value of the n-type impurity concentration in the mountain-shaped distribution M2 is higher than 1×10¹⁸ cm⁻³ and lower than 1×10¹⁹ cm⁻³. Other configurations of the second embodiment are the same as those of the first embodiment. In the process of implanting the n-type impurity into the cathode regions 66, the n-type impurity is implanted locally at a high concentration within the depth range of the second cathode region 66b, thereby forming the mountain-shaped distribution M2.

When the mountain-shaped distribution M2 is formed as in the second embodiment, the n-type impurity concentration in the second cathode region 66b becomes high, and the activation rate of the n-type impurity in the second cathode region 66b can be made lower. This makes it possible to further shorten the carrier lifetime in the second cathode region 66b. As a result, it is possible to more effectively suppress the recovery loss of the diode.

### Third Embodiment

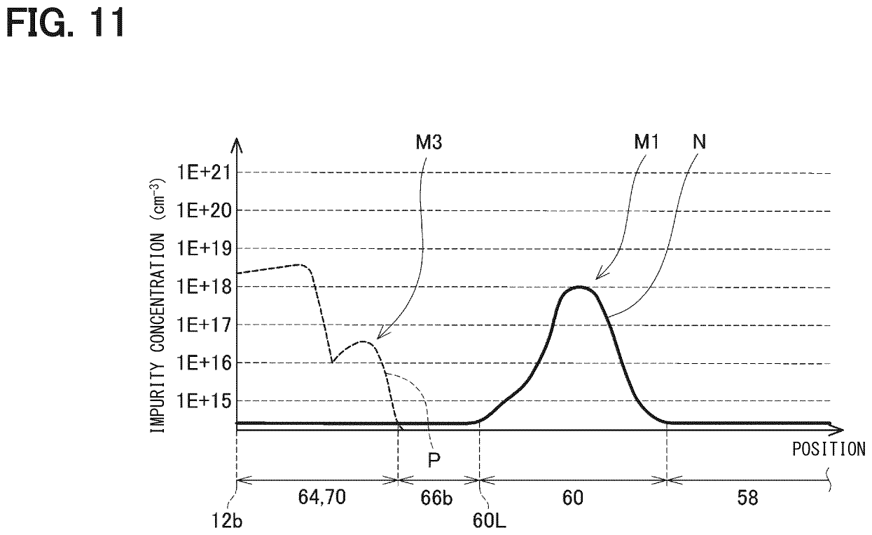

FIG. 11 shows an impurity concentration distribution at the positions along the lines B-B and C-C of a semiconductor device according to a third embodiment. In the third embodiment, the collector region 64 and the surge suppression region 70 have a mountain-shaped distribution M3 above the box profile. Other configurations of the third embodiment are the same as those of the first embodiment. In the process of implanting the p-type impurity into the collector region 64 and the surge suppression regions 70, the p-type impurity is implanted so as to have a peak above the heated area 94, thereby forming the mountain-shaped distribution M3. By forming the mountain-shaped distribution M3 in this way, the collector region 64 and the surge suppression regions 70 can be made thicker than those in the first embodiment. In the first embodiment, the thicknesses of the collector region 64 and the surge suppression regions 70 are approximately the same as or thinner than the first cathode region 66a. On the other hand, according to the third embodiment, the thicknesses of the collector region 64 and the surge suppression regions 70 can be made thicker than the first cathode region 66a.

In the first to third embodiments described above, the gate electrode of the IGBT is of the trench type. Alternatively, the gate electrode of the IGBT may be of the planar type.

Although the embodiments have been described in detail above, these are merely examples and do not limit the scope of the present disclosure. The techniques described in the present disclosure include various modifications of the specific examples illustrated above. The technical elements described in the present specification or the drawings exhibit technical usefulness alone or in various combinations, and are not limited to the combinations described herein. In addition, the techniques illustrated in the present specification or drawings achieve objectives at the same time, and achieving one of the objectives itself has technical usefulness.

What is claimed is:

1. A semiconductor device comprising:
a semiconductor substrate having an insulated gate bipolar transistor (IGBT) region and a diode region;
an upper electrode in contact with an upper surface of the semiconductor substrate in the IGBT region and the diode region;
a lower electrode in contact with a lower surface of the semiconductor substrate in the IGBT region and the diode region; and
a gate electrode, wherein
the semiconductor substrate includes:
an emitter region of an n-type in contact with the upper electrode in the IGBT region;
an upper p-type region distributed across the IGBT region and the diode region and in contact with the upper electrode in the IGBT region and the diode region;
a drift region of the n-type disposed below the upper p-type region, distributed across the IGBT region and the diode region, and separated from the n-type emitter region by the upper p-type region;
a field stop region of the n-type disposed below the drift region, distributed across the IGBT region and the diode region, and having an n-type impurity concentration higher than that of the drift region, the n-type impurity concentration having a mountain-shaped distribution along a thickness direction of the semiconductor substrate;
a collector region of a p-type disposed below the field stop region in the IGBT region, and in contact with the lower electrode;
a plurality of cathode regions of the n-type disposed below the field stop region in the diode region, and in contact with the lower electrode; and
a plurality of surge suppression regions of the p-type disposed below the field stop region in the diode region, and in contact with the lower electrode,
the gate electrode faces the upper p-type region between the emitter region and the drift region via a gate insulating film,
in the diode region, the plurality of cathode regions and the plurality of surge suppression regions are alternately arranged along a specific direction on the lower surface of the semiconductor substrate,
each of the plurality of cathode regions includes:
a first cathode region in contact with the lower electrode, and having an n-type impurity concentration of 1×10¹⁹ cm⁻³ or more; and
a second cathode region disposed between the first cathode region and the field stop region, and having an activation rate of n-type impurity of 85% or less.

2. The semiconductor device according to claim 1, wherein
the second cathode region has an n-type impurity concentration with a mountain-shaped distribution along the thickness direction of the semiconductor substrate.

3. The semiconductor device according to claim 2, wherein
the n-type impurity concentration with the mountain-shaped distribution of the second cathode region has a peak value higher than 1×10¹⁸ cm⁻³ and lower than 1×10¹⁹ cm⁻³.

4. A method for manufacturing a semiconductor device, the semiconductor device including:
a semiconductor substrate having an insulated gate bipolar transistor (IGBT) region and a diode region;
an upper electrode in contact with an upper surface of the semiconductor substrate in the IGBT region and the diode region;
a lower electrode in contact with a lower surface of the semiconductor substrate in the IGBT region and the diode region; and
a gate electrode, wherein
the semiconductor substrate includes:
an emitter region of an n-type in contact with the upper electrode in the IGBT region;
an upper p-type region distributed across the IGBT region and the diode region and in contact with the upper electrode in the IGBT region and the diode region;
a drift region of the n-type disposed below the upper p-type region, distributed across the IGBT region and the diode region, and separated from the n-type emitter region by the upper p-type region;
a field stop region of the n-type disposed below the drift region, distributed across the IGBT region and the diode region, and having an n-type impurity concentration higher than that of the drift region, the n-type impurity concentration having a mountain-shaped distribution along a thickness direction of the semiconductor substrate;
a collector region of a p-type disposed below the field stop region in the IGBT region, and in contact with the lower electrode;
a plurality of cathode regions of the n-type disposed below the field stop region in the diode region, and in contact with the lower electrode; and
a plurality of surge suppression regions of the p-type disposed below the field stop region in the diode region, and in contact with the lower electrode,
the gate electrode faces the upper p-type region between the emitter region and the drift region via a gate insulating film,
in the diode region, the plurality of cathode regions and the plurality of surge suppression regions are alternately arranged along a specific direction on the lower surface of the semiconductor substrate,
each of the plurality of cathode regions includes:
a first cathode region in contact with the lower electrode, and having an n-type impurity concentration of 1×10¹⁹ cm⁻³ or more; and
a second cathode region disposed between the first cathode region and the field stop region, and having an activation rate of n-type impurity of 85% or less,
the method for manufacturing the semiconductor device, comprising:
forming the collector region, the plurality of cathode regions, and the plurality of surge suppression regions by ion-implantation of a p-type impurity and an n-type impurity to the lower surface of the semiconductor substrate; and
applying a laser beam to the lower surface of the semiconductor substrate, after the forming of the collector region, the plurality of cathode regions, and the plurality of surge suppression regions, wherein
the applying of the laser beam includes forming a heated area of 950° C. or more in a surface layer portion near the lower surface of the semiconductor substrate, and
a thickness of the heated area is less than the thickness of the plurality of cathode regions.
